(19) United States
(12) Patent Application Publication
(10) Pub. No.: US 2025/0229334 A1
(43) Pub. Date: Jul. 17, 2025

(54) INTELLIGENT SCAN SEQUENCE OPTIMIZATION FOR POWDER BED FUSION ADDITIVE MANUFACTURING USING LINEAR SYSTEMS THEORY

(71) Applicant: The Regents of the University of Michigan, Ann Arbor, MI (US)

(72) Inventors: Keval RAMANI, Vasco-Da-Gama (IN); Chinedum OKWUDIRE, Birmingham, MI (US); Chuan HE, Ann Arbor, MI (US)

(73) Assignee: The Regents of the University of Michigan, Ann Arbor, MI (US)

(21) Appl. No.: 18/699,090

(22) PCT Filed: Oct. 7, 2022
(86) PCT No.: PCT/US2022/045990

§ 371 Date: Apr. 5, 2024

Related U.S. Application Data
(60) Provisional application No. 63/253,228, filed on Oct. 7, 2021.

(51) Int. Cl. B22F 10/366; B22F 10/28; B22F 10/368; B22F 10/85; B33Y 10/00; B33Y 50/02

(52) U.S. Cl. CPC B22F 10/366; B22F 10/28; B22F 10/368; B22F 10/85; B33Y 10/00; B33Y 50/02

(57) ABSTRACT

An approach for intelligent online scan sequence optimization to achieve uniform temperature distribution in LPBF using a control theoretic approach. The thermal dynamics of the LPBF process is modeled using the finite difference method and the next best feature (for example, stripe or island) that minimizes a thermal uniformity metric is found using a control theoretic approach. In simulations, the present approach yields up to 8.4 times improvement in thermal uniformity compared to existing heuristic approaches.

### CROSS-REFERENCE TO RELATED APPLICATIONS

This application claims the benefit of U.S. Provisional Application No. 63/253,228, filed on Oct. 7, 2021. The entire disclosure of the above application is incorporated herein by reference.

### FIELD

The present disclosure relates to an intelligent scan sequence optimization for laser powder bed fusion additive manufacturing using linear systems theory.

### BACKGROUND AND SUMMARY

This section provides background information related to the present disclosure which is not necessarily prior art. This section provides a general summary of this disclosure, and is not a comprehensive disclosure of its full scope or all of its features.

Laser powder bed fusion (LPBF) is an increasingly popular approach for additive manufacturing (AM) of metals (and other materials). It is used in various industries, ranging from aerospace to biomedical. It builds three-dimensional (3D) parts by using a high-power laser to selectively fuse powder layer-by-layer. Compared with other AM techniques for metals, LPBF is popular for fabricating parts with intricate features and dense microstructure at relatively high tolerances and build rates. However, parts produced by LPBF are prone to residual stresses, deformations, and other defects linked to non-homogeneous temperature distribution during the process. Therefore, controlling the thermal evolution of the process is the key factor in mitigating these defects and improving part quality in LPBF.

Several works have revealed the importance of scanning strategy in achieving uniform temperature distribution in LPBF. The term scanning strategy is often used in the literature to refer to disparate aspects of laser scanning in LPBF. Here, we use the term in its broadest sense which includes all process parameters associated with laser scanning in LPBF, e.g., laser power, scan speed, hatch spacing, scan pattern and scan sequence. Scanning strategy is often selected by round-robin testing, trial and error, or heuristics. However, given its importance in determining temperature distribution, a growing body of research is focused on controlling various elements of scanning strategy.

One element of scanning strategy that has received relatively little attention is scan sequence. Scan sequence refers to the order in which a specific infill pattern is scanned. For example, two of the most commonly used scan patterns in practice are the stripe and island (see FIGS. 1A & 1B). Scan sequence in these examples could mean the order in which each line in the stripe pattern is scanned or the order in which each island in the island pattern is scanned. Focusing on the island example, there are few common options of scan sequences available, e.g., random, successive, successive chessboard, and least heat influence (LHI) chessboard. Researchers have shown that the order in which the islands are scanned affects temperature distribution significantly.

Given the importance of scan sequence, we have sought to determine optimal scan sequence for the chessboard scan pattern, offline, using heuristic methods and genetic algorithm (GA) to generate uniform temperature distribution throughout a printed layer. However, a major weakness of their heuristic or GA optimization strategy is that it is purely geometric. They do not utilize a thermal model, rather they try to make temperature uniform by maximizing the distance between the currently and previously scanned islands. Moreover, the optimization approach adopted by using genetic algorithms is inefficient, as the number of scan sequences from which to determine the optimal grows factorially with the number of features in a pattern. For example, a stripe pattern with only 10 stripes results in 3.6 million different sequences. Therefore, a more efficient approach is necessary for online scan sequence optimization, which must be completed within the interlayer time in LPBF (typically less than one minute).

According to the principles of the present teachings, an intelligent approach is provided that uses physics-based models and feedback from sensors to efficiently determine optimal scan sequence online, layer-by-layer. This technique is achieved in two phases (see FIG. 2):
Phase I: Physics-based scanning
Phase II: Physics-based and data-driven scanning

Phase I (see FIG. 2) of the present disclosure focuses on developing physics-based temperature distribution models that can be used for combinatorial optimization to find an optimal scan sequence. This will involve developing reasonably accurate thermal models and an efficient process for optimizing scan sequence using the models. The goal of Phase II (see FIG. 2) is to complement the model-based strategy in Phase I with data-driven learning to mitigate the effect of uncertainty, nonlinearity, and parameter variation.

The key novelty and contribution of this disclosure is the use of a linear physics-based thermal model to efficiently optimize scan sequence via control theory. The temperature evolution is described using the finite difference method (FDM) and expressed as a linear state space model. Using the model, a computationally efficient optimization based on optimal control theory is developed and used to select a scan sequence that minimizes a thermal uniformity metric.

This disclosure further presents the present control theoretic approach for scan sequence optimization using a linear state-space thermal model of LPBF formulated using FDM, two case studies to demonstrate the effectiveness of the present approach, and conclusions, and further provides discussion of future work.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIGS. 1A-1B are two common scan patterns for a layer in LPBF, an island and a stripe.

FIG. 2 is a flowchart for the intelligent online scan sequence optimization framework.

FIG. 3 is a finite difference model used, without loss of generality, for the case studies in this disclosure.

FIGS. 4A-4B is a diagram depicting the assumption that the laser heat acts at the center of each element in an actual situation and a simplified assumption.

FIG. 5 is a thermal uniformity metric for different scan sequences as a function of number of islands scanned.

FIG. 6 is a scan sequence for the present, successive, successive chessboard, and LHI chessboard island scan strategies.

FIG. 7 is a temperature distribution of 2.5 cm by 2.5 cm scanned area for Case 1 at three instances during the scanning process.

FIG. 8 is a thermal uniformity metric for different scan sequences as a function of number of stripes scanned.

FIG. 9 is a pictorial depiction of present optimal scan sequence for Case 2 after scanning the entire 2.5 cm by 2.5 cm area.

FIG. 10 is a temperature distribution of 2.5 cm by 2.5 cm scanned area for Case 2 at three instances during the scanning process.

FIG. 11 is a flowchart illustrating an approximate approach for optimal solution using multiple lasers.

FIG. 12 is a plan view of a stainless-steel plate used to demonstrate the effectiveness of ML-PBF SmartScan involving the use of ML-PBF systems to maximize productivity by using two fully overlapping lasers to scan the same area.

FIG. 13 presents the optimal sequence obtained by SmartScan as a colormap.

FIG. 14 is a graph that illustrates a temperature uniformity metric R for each sequence.

FIG. 15 is a simulated temperature distribution for all scanning sequences at four instances; i.e., when 25%, 50%, 75% and 100% of the scanning process is completed.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of this disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

This disclosure discusses the thermal modelling of the LPBF process using FDM and presents an optimization approach based on control theory to find the best scan sequence for a layer (also referred to as SmartScan).

### Thermal Model Using the Finite Difference Method

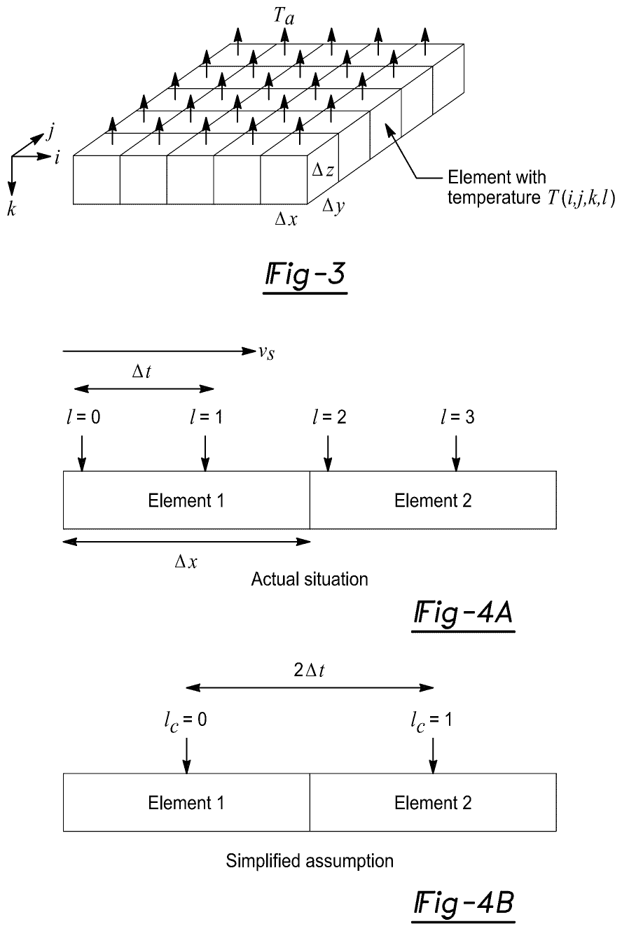

The heat conduction in a medium with conductivity kt and diffusivity α is governed by the equation

$$\frac{{\partial }^{2} T}{\partial {x}^{2}} + \frac{{\partial }^{2} T}{\partial {y}^{2}} + \frac{{\partial }^{2} T}{\partial {z}^{2}} + \frac{u}{{k}_{1}} = \frac{1}{α} \frac{\partial T}{\partial t} \qquad ( 1 )$$

where T is the temperature, x, y and z are the coordinates, t is time and u is the power per unit volume. The FDM can be used to model heat conduction and Eq. (1) can be written as

$$\frac{T ( i + 1 , j , k , l ) + T ( i - 1 , j , k , l ) - 2 T ( i , j , k , l )}{Δ {x}^{2}} + \frac{T ( i , j + 1 , k , l ) + T ( i , j - 1 , k , l ) - 2 T ( i , j , k , l )}{Δ {y}^{2}} + \frac{T ( i , j , k + 1 , l ) + T ( i , j , k - 1 , l ) - 2 T ( i , j , k , l )}{Δ {z}^{2}} + \frac{u ( i , j , k , l )}{{k}_{1}} = \frac{1}{α} \frac{T ( i , j , k , l + 1 ) - T ( i , j , k , l )}{Δ t} \qquad ( 2 )$$

where Δx, Δy and Δz are the dimensions of the element cuboid (see FIG. 3), i, j and k are the spatial indices of the elements, l is the temporal index (i.e., t=lΔt), Δt is the time step and T(i,j,k,l) is the temperature of element located at (i,j,k) at time l. Rearranging Eq. (2) gives the state equation

$$T ( l + 1 ) = AT ( l ) + Bu ( l ) \qquad ( 3 )$$

where T(l) is the state vector comprising of temperatures of all elements at time l, A is the state matrix, B is the input matrix and u(l) denotes the power input to the elements at time l.
Remark 1: The vector u(J) is a sparse vector. Only elements experiencing the effect of the laser heat at any given time/have non-zero values of u(J). In this disclosure, we assume that the laser is a point source that heats one element at a time. Hence only one member of the vector has a non-zero value at any given time.
Remark 2: The FDM-based state-space formulation allows for different types of boundary conditions. However, this disclosure, without loss of generality, assumes that the top surface experiences convection (with an ambient temperature Ta, see FIG. 3) and the remaining five faces are insulated (e.g., due to the presence of un-sintered powder around them). Only one layer of height equal to the element height (Δz) is considered.

Convection at the top surface can be incorporated into the model using the heat sink solution as shown in FIG. 3. The power per unit volume term in Eq. (2) can be expressed as

$$u ( i , j , 1 , l ) = {u}_{s} ( i , j , 1 , l ) - {u}_{conv} ( i , j , 1 , l ) \qquad ( 4 )$$

where uₛ and u_{conv} respectively denote the contributions of the laser source and convection to the total power for the element. The convection term can be expressed as

$${u}_{conv} ( i , j , 1 , l ) = \frac{h}{Δ z} ( T ( i , j , 1 , l ) - {T}_{a} ) \qquad ( 5 )$$

where h and Tₐ denote the convection coefficient and ambient temperature, respectively. The power due to convection can be easily embedded into the AT(l) term of the state equation (Eq. (3)) by addition of an additional state Ta that does not vary with time.

Typical scan patterns such as unidirectional, zigzag, cross-hatching, spiral, island, etc. consist of simple constant velocity (vₛ) and constant power (P) stripes and each stripe can be visualized as heating of a one-dimensional array of cuboidal elements. Our FDM model assumes that the laser heat on an element acts at the center of the element (as shown in FIG. 4). The number of time steps spent on an element can be approximated as

$${n}_{c} \approx \frac{Δ x}{{v}_{x} Δ t} \qquad ( 6 )$$

The corresponding state equation for heating of an element can then be written as

$$T ( {l}_{c} + 1 ) = {A}_{c} T ( {l}_{c} ) + {b}_{c} ; {A}_{c} {=}^{Δ} {A}^{{n}_{c}} ; {b}_{c} {\sum }_{m - 0}^{{n}_{c} - 1} {A}^{m} Bu ( m ) ; {l}_{c} = {n}_{c} l \qquad ( 7 )$$

Different from Eq. (3), the state-space model of Eq. (7) has a sampling interval of n_{c}Δt (see FIG. 4). Similarly, this idea can be extended to any feature (e.g., stripe or island) of a scan to obtain a feature-level state-space representation given by

$$T ( {l}_{p} + 1 ) = {A}_{p} T ( {l}_{p} ) + {b}_{p} ; {A}_{p} {=}^{Δ} {A}^{{n}_{p}} ; {b}_{p} {\sum }_{m - 0}^{{n}_{p} - 1} {A}^{m} Bu ( m ) ; {l}_{p} = {n}_{p} l \qquad ( 8 )$$

where nₚ is the number of time steps required to execute a feature (e.g., stripe or island) of the pattern. Note that the state equation given by Eq. (8) has a sampling time nₚΔt.

### Optimization Using Control Theoretic Approach

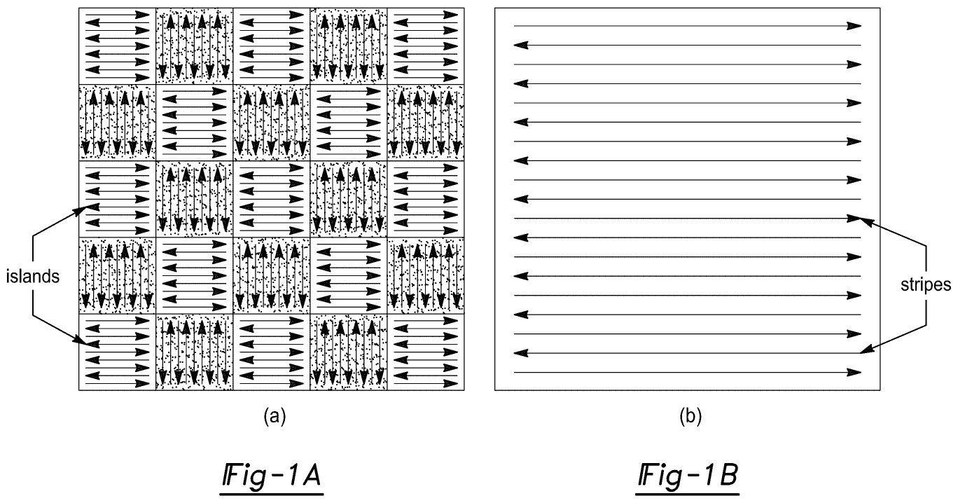

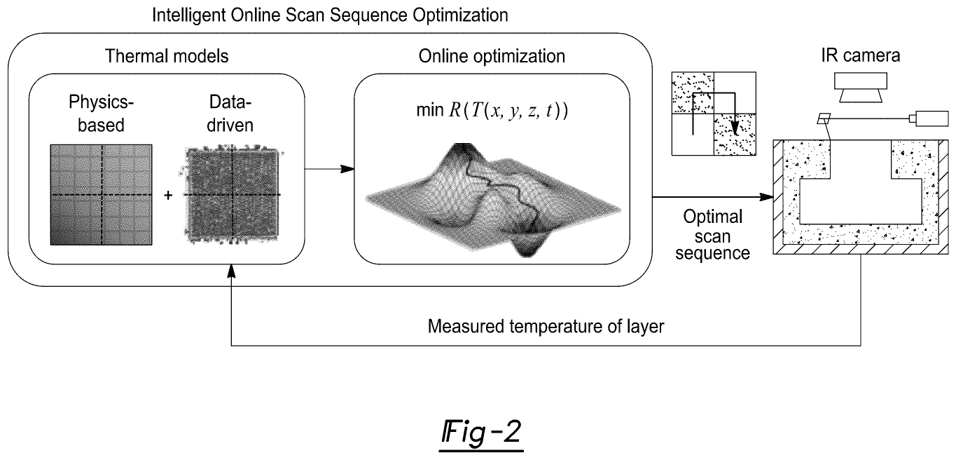

Based on the assumption that each layer in LPBF can be divided into similar features such as stripes or islands for the purpose of scanning (see FIG. 1), the objective is to find an optimal scan sequence such that at the end of each feature the following temperature uniformity metric R(lₚ) is minimized

$$R ( {l}_{p} ) = \sqrt{\frac{{\sum }_{i , j , k} {( T ( i , j , k , {l}_{p} ) - {T}_{avg} ( {l}_{p} ) )}^{2}}{{n}_{c} {T}_{m}^{2}}} \qquad ( 9 )$$

where T_{avg}(lₚ) is the average temperature of elements T(i,j,k,lp) at time lₚ, nₑ is the number of elements and Tₘ is the melting temperature of the material. Note that the definition of R(lₚ) is altered slightly from that used in by adopting the melting temperature of the material in the denominator, rather than the average temperature. A lower value of R(lₚ) implies more uniform temperature distribution. Notice that R(lₚ) is a function of state vector T(lₚ) and can be expressed as

$$R ( {l}_{p} ) = {‖ {C}_{eq} T ( {l}_{p} ) ‖}_{2} ; {C}_{eq} = \frac{1}{\sqrt{{n}_{e} {T}_{m}}} [ I - \frac{{11}^{T}}{{n}_{e}} 0 ] \qquad ( 10 )$$

where I is the identity matrix, 1 is a row vector whose elements are all equal to 1, and 0 is null matrix used to account for any elements of T(lₚ) that are not needed to calculate R(lₚ)—e.g., Tₐ. The optimization problem can be formulated as

$${min}_{{u}_{eq} ( {l}_{p} )} ( R ( {l}_{p} + 1 ) = {‖ {C}_{eq} T ( {l}_{p} ) ‖}_{2} s . t . T ( {l}_{p} + 1 ) = {A}_{eq} T ( {l}_{p} ) + {B}_{eq} {u}_{eq} ( {l}_{p} ) \qquad ( 11 )$$

where A_{eq}=Aₚ, the columns of B_{eq} represent corresponding vectors bₚ(see Eq. (8)) for each feature and u_{eq}(lₚ) is a vector comprising of only one element equal to 1 and all other elements equal to 0. The location of 1 in u_{eq}(lₚ) represents the column of B_{eq} and hence the feature to be scanned. The objective of the optimization problem can be written as

$${‖ {C}_{e q} T ( {l}_{p} + 1 ) ‖}_{2}^{2} = {‖ {C}_{e q} {A}_{e q} T ( {l}_{p} ) + {C}_{e q} {B}_{e q} {u}_{e q} ( {l}_{p} ) ‖}_{2}^{2} = {u}_{e q}^{T} ( {l}_{p} ) {B}_{e q}^{T} {C}_{e q}^{T} {C}_{e q} {B}_{e q} {u}_{e q} ( {l}_{p} ) + 2 {T}^{2} ( {l}_{p} ) {A}_{e q}^{T} {C}_{e q}^{T} {C}_{e q} {B}_{e q} {u}_{e q} ( {l}_{p} ) + {T}^{T} ( {l}_{p} ) {A}_{e q}^{T} {C}_{e q}^{T} {C}_{e q} {A}_{e q} T ( {l}_{p} ) \qquad ( 12 )$$

The third term of the summation is independent of u_{eq}(lₚ), thus does not affect the optimization. The vector u_{eq}(lₚ) has one element equal to 1 and all others equal to 0 which results in only the diagonal terms of B_{eq}^{T}C_{eq}^{T}C_{eq}B_{eq} affecting the summation. Hence, the optimization problem can be formulated as

$${min}_{i} {λ}_{i} s . t . λ = \underbrace{diag ( {B}_{e q}^{T} {C}_{e q}^{T} {C}_{e q} {B}_{e q} )}_{Γ} + \underbrace{2 {B}_{e q}^{T} {C}_{e q}^{T} {C}_{e q} {A}_{e q}}_{Λ} T ( {l}_{p} ) \qquad ( 13 )$$

where λᵢ are elements of A. Since F and A are known a priori, they can be pre-computed offline. Accordingly, the process for determining optimal scan sequence using our present control theoretic approach is summarized in Remark 3.
Remark 3: Starting from time lₚ=0 with known T(0), determining the optimal scan sequence at any given time step lₚ is as follows: (i) calculate the vector A from Eq. (13) and determine the index i corresponding to its smallest element; (ii) select the optimal feature at time lₚ that minimizes R(lₚ+1) by entering 1 as the element of u_{eq}(lₚ) corresponding to index i; (iii) calculate the optimal thermal distribution T(lₚ+1) using the state equation in Eq. (8); (iv) advance to time lₚ+1 and repeat the process from (i).
Remark 4: Note that the point-to-point positioning time of the laser is not included in the formulation above because it is negligible compared to the time spent scanning, as observed by. This is because the point-to-point positioning speed (also known as jump speed) is typically 5 to 10 times higher than the scanning speed.

Here, we demonstrate the effectiveness of the present approach using two case studies: (1) an island scan pattern (see FIG. 1A); and (2) a stripe scan pattern (see FIG. 1B). In both cases, we assume that a 2.5 cm by 2.5 cm layer of solid steel is scanned with convection at its top surface and the other five surfaces are insulated, as depicted in FIG. 3. The parameters for the thermal model are Δx=Δy=Δz=200 μm such that ne=125²=15,625, kₜ=24 W/mK, α=6.689×10⁻⁶ m2/s, Tₘ=1700 K, Tₐ=293 K, h=20 W/m²K, vₛ=0.6 m/s and Δt=0.3333 ms (n_{c}=1). The laser power and uniform initial temperature are 180 W and 293 K, respectively.

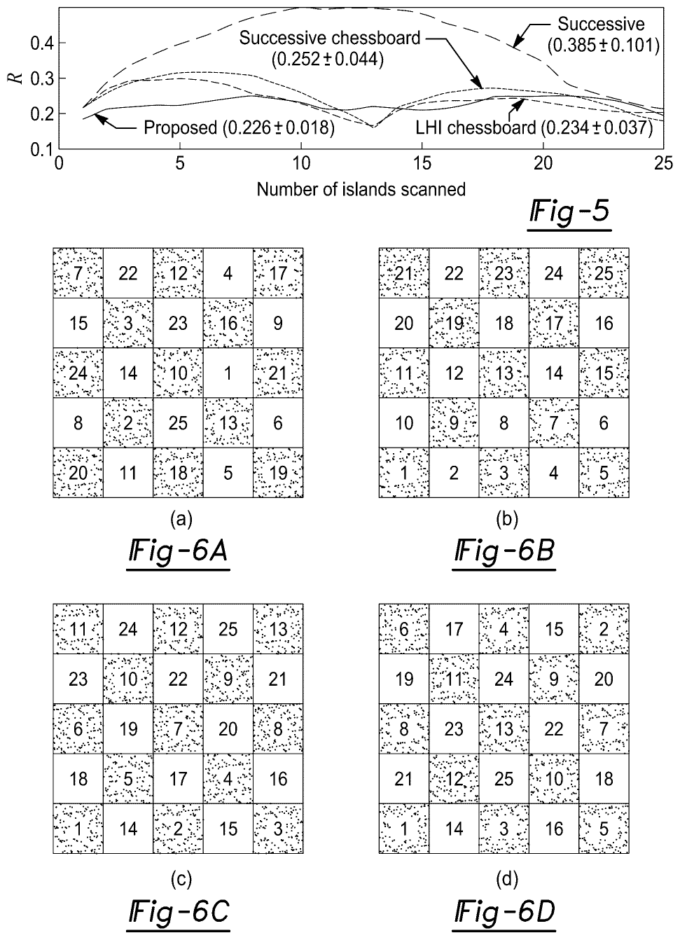

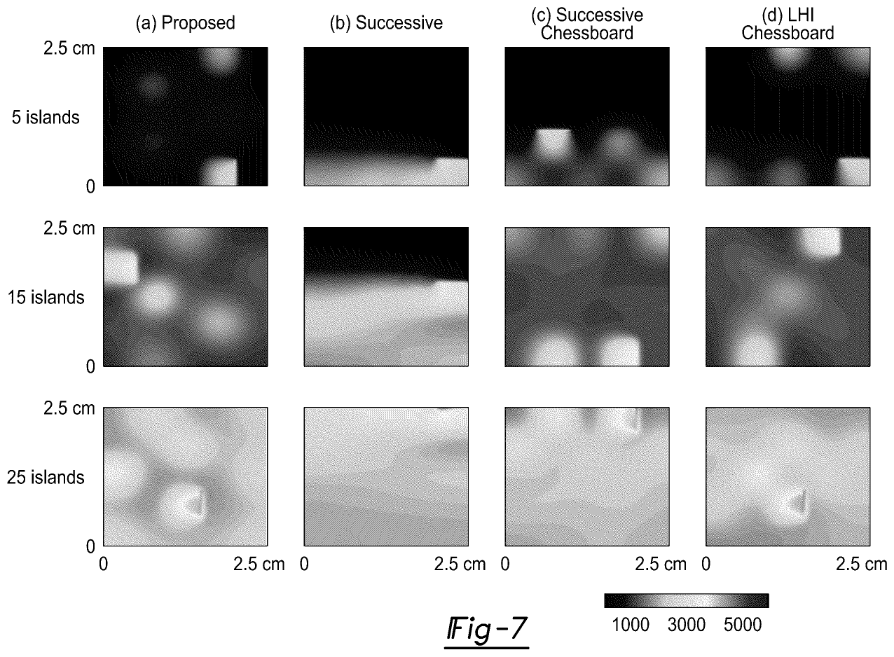

For this case study, the 2.5 cm by 2.5 cm area to be scanned is divided into 25 (0.5 cm by 0.5 cm) islands. As is typical, the direction of the scan lines is rotated by 90° for the even numbered islands relative to the odd numbered islands (see FIG. 1A). FIG. 5 shows the temperature uniformity metric as a function of the number of islands scanned. The optimal (present) scan sequence (see FIG. 6A) performs much better than the successive chessboard and LHI chessboard scan sequences (depicted in FIG. 6). Note that LHI chessboard is conceptually similar to the heuristic optimization approach. The mean and standard deviation of R is reported in FIG. 5. The present optimal approach yields 1.71, 1.11 and 1.04 times lower mean R than the successive, successive chessboard and LHI chessboard, respectively. In addition, it yields 5.64, 2.44, and 2.03 times lower standard deviation than the successive, successive chessboard and LHI chessboard, respectively. This indicates that the present optimal scan sequence yields better, and more consistent, thermal uniformity compared to the competing approaches. This fact is confirmed by FIG. 7, which shows the thermal distribution of four approaches at three instances—after 5 islands, 15 islands and 25 islands are scanned. The successive strategy results in the highest maximum temperature followed by the successive chessboard, LHI chessboard and the present approach. In addition, the gradient is much higher for the successive strategy for 5 and 15 islands, whereas the gradient is higher for chessboard (successive and LHI) strategies for 5 islands. The temperature is more evenly distributed for the present approach.
Remark 5: The temperature values shown in FIG. 7 are higher than realistic values because of several assumptions made while formulating the FDM model. For example, neglecting latent heat, assuming the laser is a point source, material properties such as conductivity and diffusivity are constant, etc. Future research shall focus on an FDM model and optimization approach without using these assumptions.

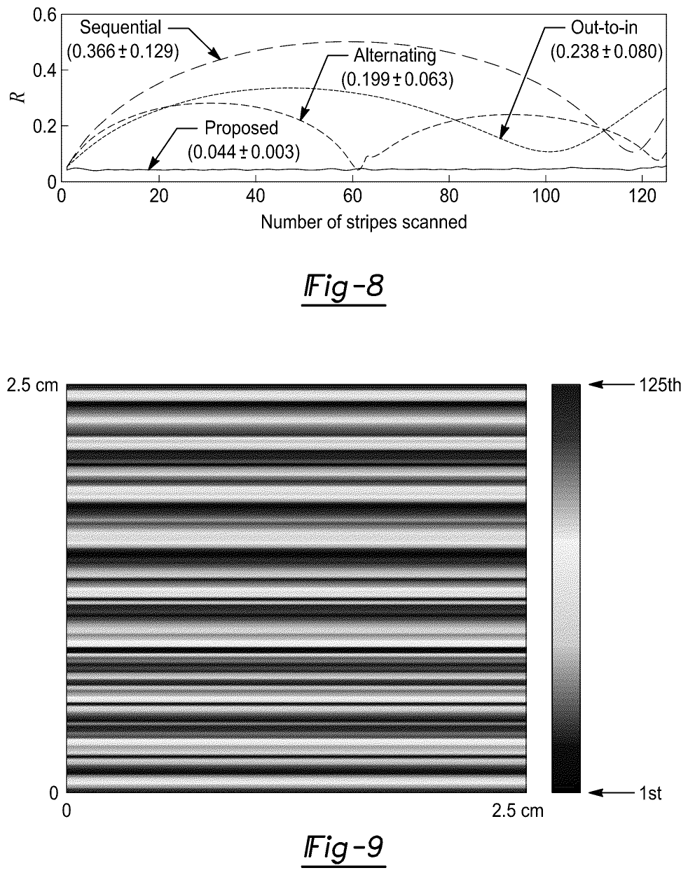

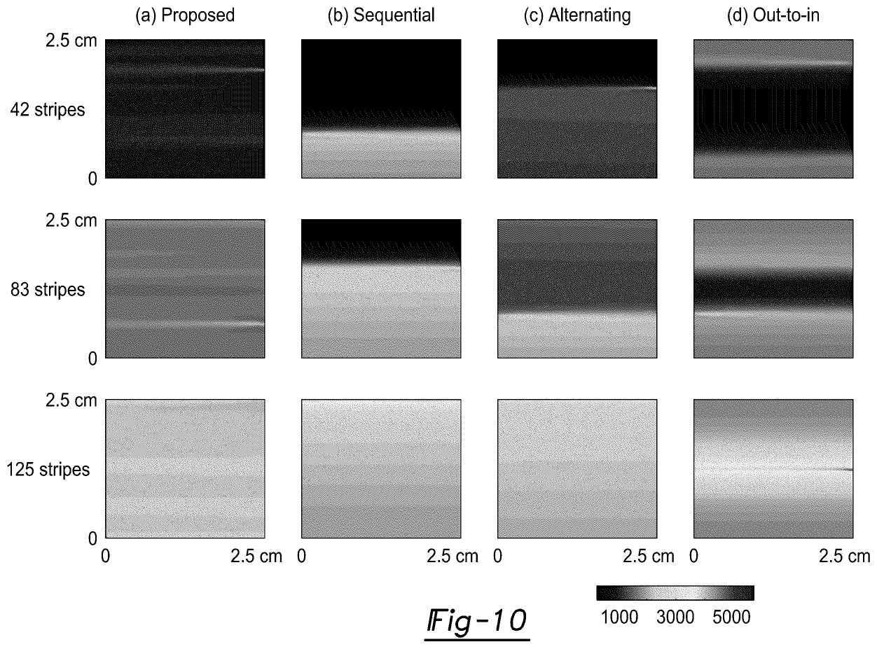

For this case study, the 2.5 cm by 2.5 cm area to be scanned is divided into 125 stripes (see FIG. 1B). FIG. 8 shows the temperature uniformity metric as a function of number of stripes scanned. (The stripes are numbered sequentially from 1 to 125 starting from the bottom edge of the layer). The present optimal scan sequence shown in FIG. 9, performs much better than the sequential (1, 2, 3, . . . , 125), alternating (1, 3, . . . , 125, 2, 4, . . . , 124) and out-to-in (1, 125, 2, 124, . . . 62, 64, 63) approaches. The mean and standard deviation of R are reported in FIG. 8. The present optimal approach yields 8.4, 4.6 and 5.5 times lower mean R than sequential, alternating, and out-to-in, respectively. In addition, it yields 49, 24 and 31 times lower standard deviation than sequential, alternating, and out-to-in, respectively. This indicates both better and more consistent thermal uniformity using the present optimal approach compared to the competing approaches. This fact is confirmed by FIG. 10 that shows the thermal distribution of four approaches at three instances—after 42, 83 and 125 stripes are scanned. The present approach results in uniform temperature distribution, whereas the sequential and alternating approaches result in large gradients for 42 and 83 stripes. The out-to-in approach results in large gradients for all three cases.
Remark 6: The present approach performs much better for the stripe strategy compared to the island strategy because the stripe pattern (with 125!options) provides more flexibility than the island pattern (with 25!options) for optimization.
Remark 7: For Cases 1 and 2 it takes only 7 and 18 seconds, respectively, for online computation of the optimal scan sequences following the process outlined in Remark 3, after the constant matrices (e.g., Γ and Λ) have been pre-computed offline. This implies that the present approach is computationally efficient and can implemented within the interlayer time in LPBF. The computations are performed on a computer with an Intel® Xeon® CPU E3-1241 v3 @3.50 GHz processor and 16 GB RAM.

The LPBF AM process is gaining popularity, particularly for producing metallic parts. However, the quality of LPBF parts deteriorates significantly if the temperature evolution is nonuniform. Hence, a lot of research has focused on monitoring and control of the temperature field.

Optimal control of scanning strategy parameters such as laser power and scanning velocity has been explored in the literature. However, optimization of the scan sequence has received very little attention. This disclosure presents, for the first time, a control theoretic approach for achieving intelligent online scan sequence optimization. A linear state-space thermal model of the LPBF process is formulated using the finite difference method. Using optimal control theory, the next feature (island or stripe) to be scanned in the sequence is determined such that a temperature uniformity metric is minimized at the end of scanning the feature. This greedy optimization process is repeated until all features in the layer are scanned.

The current model assumes that the laser source is concentrated at a point and the material properties such as conductivity and diffusivity do not vary with location or temperature. In addition, the effect of latent heat is not considered. Future work will focus on incorporating these effects in the model and optimizing the scan sequence. Use of basis functions and distributed/parallel/cloud computing will be explored to ensure that the computational efficiency of the current approach can be extended to large-dimension parts. In addition, the current approach performs a greedy optimization, which might result in a more uniform temperature during the early evolution of the LPBF process but result in large temperature gradients at the end of the process. Hence, a receding horizon approach to ensure a more uniform temperature distribution throughout the process is needed. In addition, the developed approach will be implemented experimentally on a PANDA 11 open-architecture LPBF machine available at the University of Michigan.

Computation and optimization using the FDM model can become cumbersome as the number of elements/states grow (for example, due to an increase in the size of the layer or the addition of a substrate to the model). This section describes the use of radial basis functions to reduce the higher-order FDM model.

For any given time step, l, the temperature T at location (i,j,k) can be expressed using radial basis functions as follows

$$T ( i , j , k ) = {\sum }_{p = 1}^{s} {w}_{p} φ ( {r}_{p} ) ; φ ( {r}_{p} ) = {e}^{- {( ε {r}_{p} )}^{2}} ; {r}_{p} {=}^{Δ} {‖ [ \begin{matrix}i \\ j \\ k\end{matrix} ] - [ \begin{matrix}{i}_{p} \\ {j}_{p} \\ {k}_{p}\end{matrix} ] ‖}_{2} \qquad ( 14 )$$

where ε is the shape parameter; φ is the radial basis function, [iₚ jₚ kₚ]^{T} is the location of the representation elements; s is the number of representation elements; and rₚ (p=1, 2, . . . , s) is the Euclidean distance between the element at (i, j, k) and the representation element (iₚ, jₚ, kₚ). In the matrix form, Eq. 14 can be expressed as

$$T ( i , j , k ) = \underbrace{[ \begin{matrix}φ ( {r}_{1} ) & φ ( {r}_{2} ) & … & φ ( {r}_{s} )\end{matrix} ]}_{m} [ \begin{matrix}{w}_{1} \\ {w}_{2} \\ ⋮ \\ {w}_{s}\end{matrix} ] \qquad ( 15 )$$

If we consider the temperature of all elements in a layer, the state vector T can be expressed as

$$T ( {l}_{p} + 1 ) = {M}_{t} W \qquad ( 16 )$$

where W=[w₁ w₂ . . . wₛ]^{T} and Mt is obtained by aggregating m for all elements in the model. The coefficients wₚ are obtained by enforcing the interpolation conditions at the representation elements and solving the system of linear equations

$$\underbrace{[ \begin{matrix}φ ( {r}_{11} ) & φ ( {r}_{12} ) & … & φ ( {r}_{1 s} ) \\ φ ( {r}_{21} ) & φ ( {r}_{22} ) & … & φ ( {r}_{2 s} ) \\ ⋮ & ⋮ & ⋱ & ⋮ \\ φ ( {r}_{s 1} ) & φ ( {r}_{s 2} ) & … & φ ( {r}_{ss} )\end{matrix} ]}_{{M}_{r}} \underbrace{[ \begin{matrix}{w}_{1} \\ {w}_{2} \\ ⋮ \\ {w}_{s}\end{matrix} ]}_{W} = \underbrace{[ \begin{matrix}T ( {i}_{1} , {j}_{1} , {k}_{1} ) \\ T ( {i}_{2} , {j}_{2} , {k}_{2} ) \\ ⋮ \\ T ( {i}_{s} , {j}_{s} , {k}_{s} )\end{matrix} ]}_{{T}_{r}} \qquad ( 17 )$$

where r_{pq} is the Euclidean distance between elements (iₚ, jₚ, kₚ) and (i_{q}, j_{q}, k_{q}). The solution to the linear equation is given by

$$W = {M}_{r}^{- 1} {T}_{r} \qquad ( 18 )$$

Substituting Eq. 18 into Eq. (16) gives

$$T ( {l}_{p} + 1 ) = \underbrace{{M}_{t} {M}_{r}^{- 1}}_{\sum } {T}_{r} ( {l}_{p} + 1 ) = \sum {T}_{r} ( {l}_{p} + 1 ) \qquad ( 19 )$$

Substituting Eq. 19 into Eq. 8 gives

$$\sum {T}_{r} ( {l}_{p} + 1 ) = {A}_{p} \sum {T}_{r} ( {l}_{p} ) + {b}_{p} \qquad ( 20 )$$

Pre-multiplying Eq. 20 by Ω (where Ω is the pseudoinverse of Θ) gives

$$\underbrace{Ω \sum }_{= I} {T}_{r} ( {l}_{p} + 1 ) = \underbrace{Ω {A}_{p} \sum }_{{\tilde{A}}_{p}} {T}_{r} ( {l}_{p} ) + \underbrace{Ω {b}_{p}}_{{\tilde{b}}_{p}} \qquad ( 21 )$$

where I is the identity matrix. Hence, the transformed (reduced) state-space equation using radial basis functions is given by

$${T}_{r} ( {l}_{p} + 1 ) = {\tilde{A}}_{p} {T}_{r} ( {l}_{p} ) + {\tilde{b}}_{p} \qquad ( 22 )$$

Remark 8: Eq. 22 has reduced the FDM model from the total number of nₑ elements in the original formulation in Eq. 8 to the s number of representation elements, where s<<nₑ. This will enable more efficient computation and optimization for larger models.

Prior work proposed improvements to SmartScan such that SmartScan can be applied to more complex shapes. SmartScan was revised so that it can process geometries with a finite set of variable-length features.

In the optimization method in Eq. 13, Λ is dependent on the lengths of features while Γ is independent of the variation in lengths. So, when Λ is expanded, the expression is obtained as

$$\underbrace{2 {B}_{eq}^{T} {C}_{eq}^{T} {C}_{eq} {A}_{k}}_{Λ} = 2 [ \begin{matrix}{b}_{1}^{T} {C}_{eq}^{T} {C}_{eq} {A}_{1} \\ {b}_{2}^{T} {C}_{eq}^{T} {C}_{eq} {A}_{2} \\ ⋮ \\ {b}_{n}^{T} {C}_{eq}^{T} {C}_{eq} {A}_{n}\end{matrix} ] = 2 [ \begin{matrix}{b}_{1}^{T} {C}_{eq}^{T} {C}_{eq} {A}^{{e}_{1}} \\ {b}_{2}^{T} {C}_{eq}^{T} {C}_{eq} {A}^{{e}_{2}} \\ ⋮ \\ {b}_{n}^{T} {C}_{eq}^{T} {C}_{eq} {A}^{{e}_{b}}\end{matrix} ] \qquad ( 23 )$$

where the total number of features be denoted by n, labeled 1, 2, . . . , n, and let them respectively take e1, e2, . . . , en time steps to trace each feature, and e^{k} is the required number of time steps to trace k^{th} feature of the pattern whose corresponding state matrix becomes Aₖ. By formulating the Λ calculation as above, it can be brought in Eq. 13 to perform an effective and efficient optimization of the variable length.

Prior work extended the original version of SmartScan for single-laser powder bed fusion (PBF) systems to multi-laser PBF (ML-PBF) systems. This an important extension because ML-PBF systems are becoming popular in industry for increasing the build area and processing speed of PBF.

To ensure that SmartScan can be implemented efficiently for ML-PBF, an approximate method is proposed. The approximate method is characterized by the fact that at any time step Iₚ, the nₗ features to be scanned simultaneously by the nₗ lasers can be optimized sequentially as follows:
1) Determine the optimal feature for the first laser, with the other lasers turned off.
2) Calculate the intermediate temperature distribution, Tᵢₙₜ(lₚ), of the layer after the optimal feature is scanned.
3) Determine the optimal feature for the next laser using the intermediate temperature calculated in step (2), with the other lasers turned off.
4) Repeat steps (2) and (3) until the optimal features for all nₗ lasers are determined.

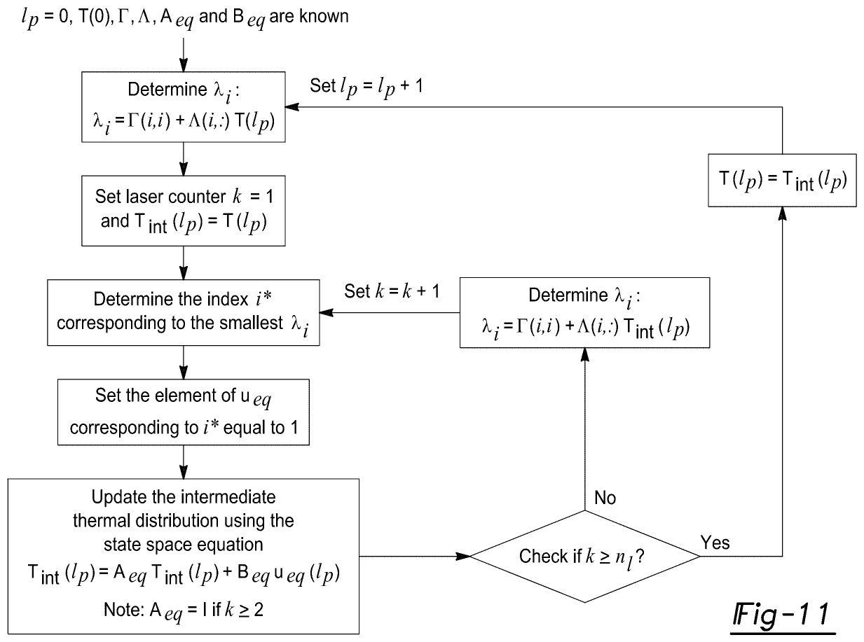

In the approximate solution, only one element of u_{eq}(lₚ) is equal to 1 when each optimal feature is determined. Thus, for each laser, the optimal solution boils down to:

$${min}_{i} {λ}_{i} \\ s . t . {λ}_{i} = Γ ( i , j ) + Λ ( i , : ) T ( {l}_{p} ) , i ∈ \{ 1 , 2 , … , {n}_{f} \} \qquad ( 24 )$$

where n_{f} refers to the total number of features and the element, Γ(i,i), refers to the i^{th} diagonal element of matrix r and A(i,:) refers to i^{th} row of matrix Λ. Note that T(lₚ)=Tᵢₙₜ(lₚ) and A_{eq}=A⁰=I for Laser 2 and beyond, indicating zero-time delay between “sequential” lasers because they are in reality acting simultaneously. The approximate approach can be summarized by the flowchart in FIG. 11.

The size of λᵢ grows linearly, rather than combinatorially, with the number of features. In essence, the approximate SmartScan solution for ML-PBF boils down to nₗ iterations of the single-laser PBF solution. This significantly improves the computational efficiency of SmartScan for ML-PBF systems.
Remark 9: The jump time of PBF is not included in any of the SmartScan solutions because it is much shorter than the scan time. However, it plays an important role in the overall productivity of the process. The SmartScan solutions for ML-PBF presented above do not designate which of the nₗ lasers is responsible for scanning each of the nₗ features of an optimal sequence at any given time step Iₚ. Therefore, features are assigned to each laser such that jump time is minimal. This is achieved by minimizing the sum of the travel distances between features selected at time step Iₚ relative to those selected at time step Iₚ−1.

Another modification made to the approximate solution is to not only optimize scan sequence but to also optimize the laser. This is achieved by defining B_{eq,sl,1} as:

$$\text{?} \qquad ( 25 )$$

$$\text{?} \text{indicates text missing or illegible when filed}$$

where B_{Pj} represents the input matrix in Eq. 11 but corresponds to the input power Pⱼ which belongs to the set {P₁, P₂, . . . , P_{nα}} of power levels that are considered in the optimization for each feature and nα is the number of power levels. Similar to the arrangement of columns in B_{eq,sl,1} shown above, the elements of u_{eq,sl,k} are arranged such that the first nf elements correspond to different features but the same power level P₁, the next n_{f} elements correspond to different features but the same power level P₂ and so on. For example, if n_{f}=100 and nα=4, then u_{eq,si,k} has 400 elements. The selection of the 1^{st} element of u_{eq,si,k} implies heating the first feature at power level P₁, while the selection of the 101^{st}, 201^{st} or 301^{st} elements imply the heating of the first feature at power levels P₂, P₃ and P₄, respectively.

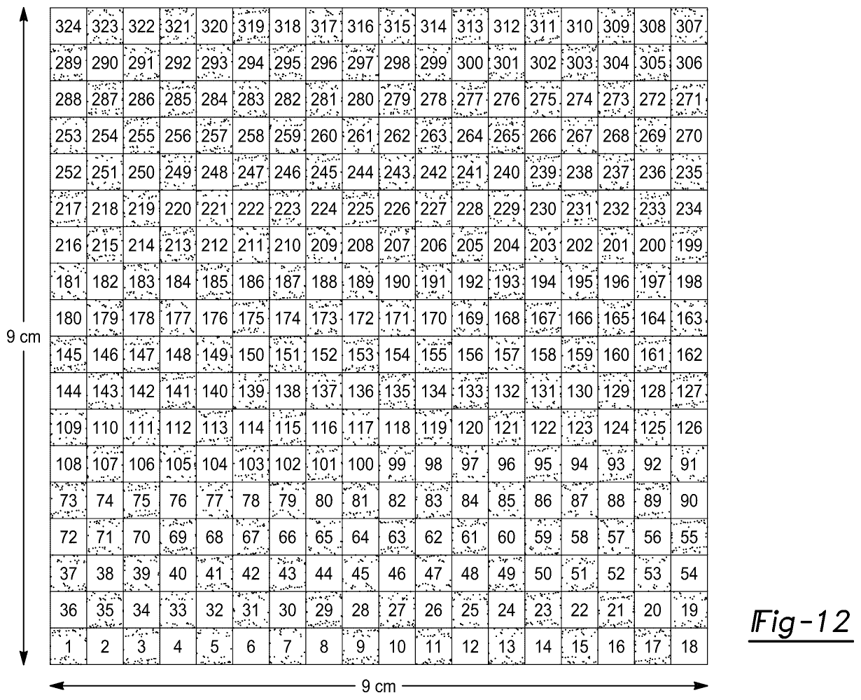

We demonstrate the effectiveness of ML-PBF SmartScan involving the use of ML-PBF systems to maximize productivity by using two fully overlapping lasers to scan the same area. An area of 9 cm×9 cm in the middle of the upper surface of a 10 cm×10 cmxl mm (L×W×H) AISI 316L stainless steel plate is divided into 18×18=324 islands of equal size, as shown in FIG. 12. The scanning vectors in the adjacent islands are rotated by 90 degrees. The FDM model has two layers to represent the plate, where the first layer has a thickness of Δz=200 μm (representing the scanned layer) and a second layer of thickness 800 μm, representing the rest of the plate's thickness. For both the layers, Δx=Δy=200 μm which results in 500×500 elements per layer and the total number of elements in the model, nₑ=500,000. The time step for simulation Δt is selected as 0.333 ms. Radial basis function (RBF) representation elements are utilized to reduce the total number of elements. The RBF elements are evenly distributed (60×60) across the top layer, with a shape parameter of ε=0.65; hence s=3600. The top and bottom surfaces of the plate experience convection whereas the peripheral surfaces are assumed to have adiabatic boundary conditions, due to their negligible surface areas. The parameters for the thermal model are summarized in Table below.

TABLE 1
Parameters used for simulations and experiments

| Parameter, symbol (Units) | Value |
|---|---|
| Laser power, P (W) | 200 |
| Laser spot diameter, 2R_{b} (μm) | 75 |
| Absorptance, η | 0.37 |
| Mark/scan speed, vₛ (mm/s) | 600 |
| Hatch spacing (μm) | 200 |
| Conductivity, kₜ (W/(mK)) | 22.5 |
| Diffusivity, α (m²/s) | 5.632 × 10⁻⁶ |
| Melting temperature, Tₘ (K) | 1658 |
| Convection coefficient, h (W/(m²K)) | 25 |
| Initial temperature, T(x, y, z, 0) (K) | 293 |
| Ambient temperature, Tₐ (K) | 293 |

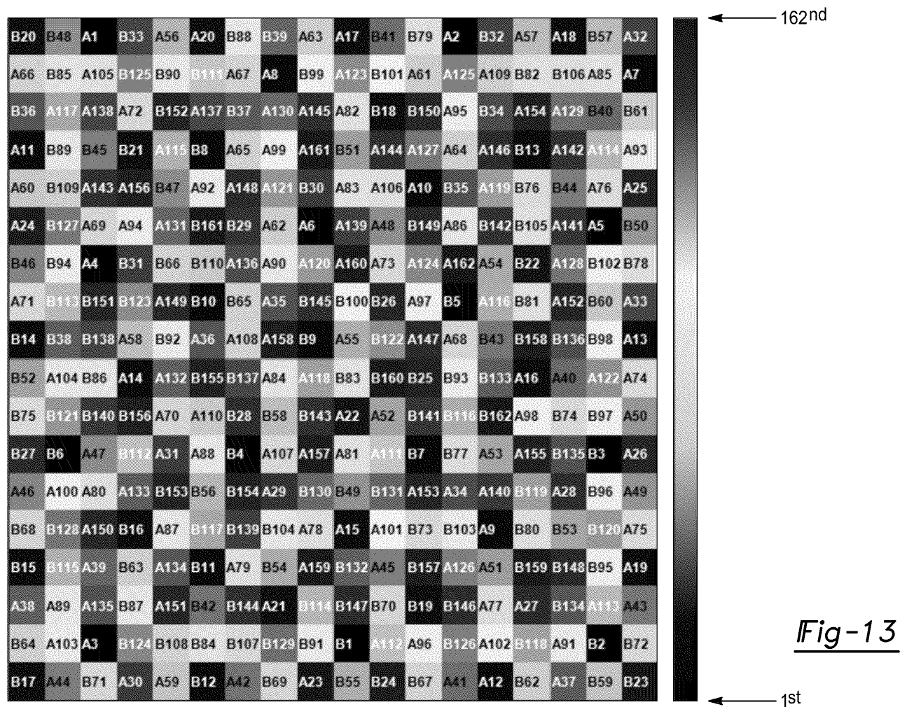

The stainless-steel plate is scanned simultaneously by two lasers (nₗ=2) denoted as Laser A and Laser B. Three heuristics sequences and SmartScan are compared in terms of the uniformity of the temperature distribution. The two lasers start working independently and are assigned sequences separately. For the successive sequence, Laser A scans islands 1 to 162 (see FIG. 12 for island numbering) in sequential order (i.e., 1, 2, 3, . . . , 162) and Laser B scans islands 163 to 324 in sequential order (i.e., 163, 164, 165, . . . , 324). Laser A for the successive chessboard sequence scans the even-numbered islands in descending order (i.e., 324, 322, 320, . . . , 2) and Laser B scans the odd-numbered islands in ascending order (i.e., 1, 3, 5, . . . , 323). The LHI sequence maximizes the pairwise Euclidean distance between the next island to be scanned and each of the already scanned islands to minimize the heat influence. The first ten entries of the LHI sequence for Laser A are: 1, 18, 153, 298, 145, 85, 229, 319, 13 and 81; and for Laser B are: 307, 324, 164, 9, 77, 221, 91, 5, 73 and 149. FIG. 13 presents the optimal sequence obtained by SmartScan as a colormap. In addition, the integer in each grid stands for the sequence of each laser, laser assignment is indicated by the letter.

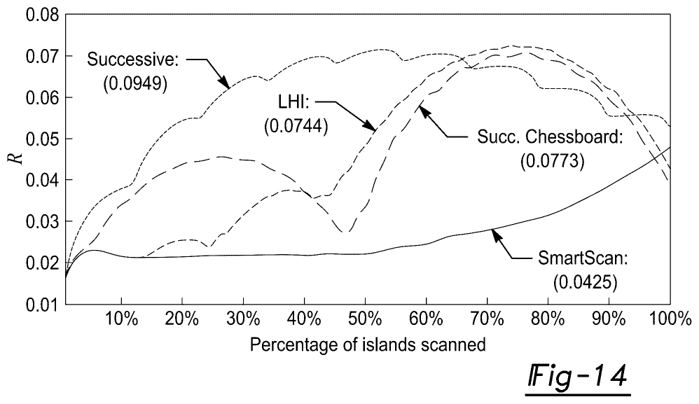

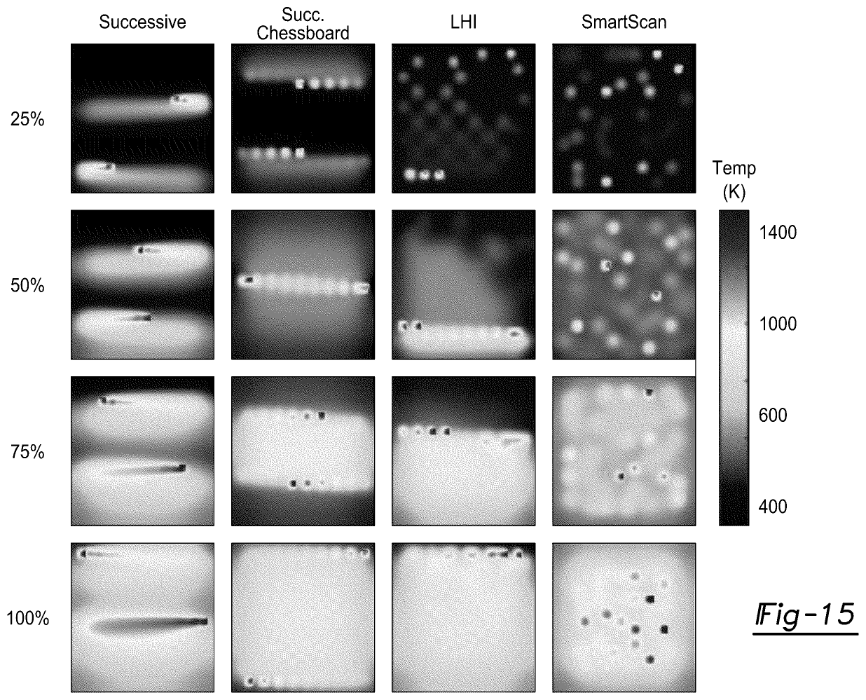

The temperature uniformity metric R for each sequence is shown in FIG. 14. It is observed that the average R produced by SmartScan is 55.2%, 45.0% and 42.9% lower than those of the successive, successive chessboard and LHI sequences, respectively. FIG. 15 additionally confirms this fact through the simulated temperature distributions for all scanning sequences at four instances; i.e., when 25%, 50%, 75% and 100% of the scanning process is completed.

The foregoing description of the embodiments has been provided for purposes of illustration and description. It is not intended to be exhaustive or to limit this disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from this disclosure, and all such modifications are intended to be included within the scope of this disclosure.

What is claimed is:

1. A method for laser powder bed fusion scan sequence to maintain uniform temperature distribution of an area of interest, the method compromising:
dividing the area of interest into a plurality of discrete island areas;
defining a first scan line in a first direction for a first set of the plurality of discrete island areas and a second scan line in a second direction for a second set of the plurality of discrete island areas;
determining an optimal scan sequence of a first laser using a linear physics-based thermal model via control theory and determining a temperature evolution using a finite difference method (FDM) expressed as a linear state space model, using the linear state space model to determine the optimal scan sequence to minimizes a thermal uniformity metric; and
actuating the first laser in response to the determined optimal scan sequence.

2. The method according to claim 1 wherein basis functions are used to reduce the size of the finite difference method.

3. A method for laser powder bed fusion scan sequence to maintain uniform temperature distribution of an area of interest, the method compromising:
dividing the area of interest into a plurality of discrete island areas;
defining a first scan line in a first direction for a first set of the plurality of discrete island areas and a second scan line in a second direction for a second set of the plurality of discrete island areas;
determining an optimal scan sequence of a first laser at any given time step lₚ by (i) calculating a vector λ of
$$λ = \underbrace{diag ( {B}_{e q}^{T} {C}_{e q}^{T} {C}_{e q} {B}_{e q} )}_{Γ} + \underbrace{2 {B}_{e q}^{T} {C}_{e q}^{T} {C}_{e q} {A}_{e q}}_{Λ} T ( {l}_{p} )$$
and
determining an index i corresponding to its smallest element; (ii) selecting an optimal feature at time lₚ that minimizes R(lₚ+1) by entering 1 as the element of u_{eq}(lₚ) corresponding to index i; (iii) calculating the optimal thermal distribution T(lₚ+1); (iv) advancing to time lₚ+1 and repeating the process from (i); and
actuating the first laser in response to the determined optimal scan sequence.

4. The method according to claim 3 further comprising:
processing geometries with a finite set of variable-length features.

5. The method according to claim 4 further comprising:
providing at least a second laser;
determining an optimal scan sequence of the second laser that is further dependent on the optimal scan sequence of the first laser; and
wherein the actuating the first laser comprises actuating the first and second lasers.

6. The method according to claim 5 wherein the actuating the first and second lasers comprises actuating the first and second lasers in sequence.

7. The method according to claim 5 further comprising:
determining an optimal power of at least one of the first and second lasers from predetermined set of power levels.
